(19) United States
(12) Patent Application Publication
(10) Pub. No.: US 2023/0140237 A1
(43) Pub. Date: May 4, 2023

(54) HEAT-CURABLE MALEIMIDE RESIN COMPOSITION, FILM, PREPREG, LAMINATE AND PRINTED-WIRING BOARD

(71) Applicant: Shin-Etsu Chemical Co., Ltd., Tokyo (JP)

(72) Inventors: Yoshihiro TSUTSUMI, Annaka-shi (JP); Shinsuke YAMAGUCHI, Annaka-shi (JP); Yuki KUDO, Annaka-shi (JP); Hiroyuki IGUCHI, Annaka-shi (JP); Fumiya HIRANO, Annaka-shi (JP); Atsushi TSUURA, Annaka-shi (JP); Tadaharu IKEDA, Annaka-shi (JP)

(73) Assignee: Shin-Etsu Chemical Co., Ltd., Tokyo (JP)

(21) Appl. No.: 17/971,310

(22) Filed: Oct. 21, 2022

(30) Foreign Application Priority Data
Nov. 1, 2021 (JP) 2021-178472
Nov. 1, 2021 (JP) 2021-178473

(51) Int. Cl. C08G 73/10; C08K 3/36; C08J 5/24; B32B 5/02; B32B 27/28

(52) U.S. Cl. CPC C08G 73/1067; C08K 3/36; C08J 5/244; B32B 5/02; B32B 27/281; C08J 2379/08; B32B 5/26

(57) ABSTRACT

Provided is a heat-curable maleimide resin composition capable of yielding a cured product having excellent dielectric properties even in the high-frequency region, a low water absorption rate, and a high glass-transition temperature. The heat-curable maleimide resin composition contains:
(A) two or more kinds of maleimide compound having at least one dimer acid frame-derived hydrocarbon group per molecule; and
(B) a reaction initiator,
wherein a cured product of the heat-curable maleimide resin composition has a dielectric tangent of not larger than 0.003 both at 10 GHz and 40 GHz.

### BACKGROUND OF THE INVENTION

### Field of the Invention

The present invention relates to a heat-curable maleimide resin composition, a film, a prepreg, a laminate and a printed-wiring board.

### Background Art

In recent years, a next-generation communication system known as 5G (millimeterwave region of 26 to 80 GHz) has prevailed, and even a next-next-generation communication system called 6G is already under development, where attempts are being made to realize a communication with a higher speed, a larger capacity and a lower latency than ever before. The realization of these communication systems requires materials for use in a high-frequency band of 3 to 80 GHz, and it is critical to reduce a transmission loss as a countermeasure for noise.

A transmission loss is a sum of a conductor loss and a dielectric loss; it is necessary to lower the roughness of the surface of a metal foil used to reduce a conductor loss. Meanwhile, since a dielectric loss is proportionate to a product of a square root of a relative permittivity and a dielectric tangent, as an insulating material, it is demanded that there be developed one with excellent dielectric properties (i.e. with a low relative permittivity and a low dielectric tangent).

Particularly, it is for substrate purposes that such insulating material with excellent dielectric properties is required. There are now increasingly employed a product known as a reactive polyphenylene ether resin (PPE) in the case of a rigid substrate; and products known as a liquid crystal polymer (LCP) and a modified polyimide (MPI) with improved properties in the case of a flexible printed-circuit board (FPC).

In this regard, reports have been made on substantially using, as a main resin of a substrate, a dimer diamine frame-containing maleimide compound (specific maleimide compound) (JP-A-2016-131243, JP-A-2016-131244, WO2016/114287 and JP-A-2018-201024). As opposed to the properties of a general maleimide resin, while a specific maleimide compound has a low glass-transition temperature (Tg) and a high coefficient of thermal expansion (CTE), it also has a number of merits such as significantly excellent dielectric properties, a flexible property, an excellent adhesive force to metals or the like, and a capability of realizing multi (high)-layering as being a heat-curable resin; a wide range of researches and developments are conducted with regard to such specific maleimide compound. However, each of these specific maleimide compounds has been mainly used alone.

Further, as described above, since a dielectric loss is proportionate to a product of a square root of a relative permittivity and a dielectric tangent, it is now more important to lower the dielectric tangent of a material for use in the high-frequency band.

In terms of dimension stability of a substrate, there is a report on using, together with a specific maleimide compound, an other aromatic maleimide compound having a high Tg (WO2016/114286); however, in the case of an aromatic maleimide compound, not only the dielectric properties tend to deteriorate in a millimeterwave region of not lower than 28 GHz, there are also problems of, for example, easily absorbing moisture, being inferior in compatibility, easily causing separation in the cured product, and likely incurring a varying quality. Here, although a higher Tg of a specific maleimide compound can be achieved by employing a maleimide compound using, in combination, a diamine other than dimer diamine (JP-A-2019-203122), JP-A-2019-203122 does not particularly mention the dielectric properties in the millimeterwave region, and it has become clear that a maleimide compound using dimer diamine and a diamine other than dimer diamine in combination has a high viscosity, which will cause problems in moldability and embedding property.

### SUMMARY OF THE INVENTION

Thus, it is an object of the present invention to provide a heat-curable maleimide resin composition capable of yielding a cured product having excellent dielectric properties even in the high-frequency region, a low water absorption rate, and a high glass-transition temperature. Further, it is also an object of the present invention to provide a heat-curable maleimide resin composition having excellent dielectric properties even in the high-frequency region, and also having an improved moldability and embedding property. Furthermore, it is yet another object of the present invention to provide an uncured/cured film, a prepreg, a laminate and a printed-wiring board each containing these heat-curable maleimide resin compositions.

The inventors of the present invention diligently conducted a series of studies to solve the above problems, and completed the invention by finding that the heat-curable maleimide resin composition shown below was able to achieve the above objects.

[1]

A heat-curable maleimide resin composition comprising:
(A) two or more kinds of maleimide compound having at least one dimer acid frame-derived hydrocarbon group per molecule; and
(B) a reaction initiator,

wherein a cured product of the heat-curable maleimide resin composition has a dielectric tangent of not larger than 0.003 both at 10 GHz and 40 GHz.

[2]

The heat-curable maleimide resin composition according to [1], wherein at least one kind of the component (A) is a maleimide compound (A-1) represented by a formula (1), and at least one other kind of the component (A) is a maleimide compound (A-2) represented by a formula (3), the formula (1) being expressed as

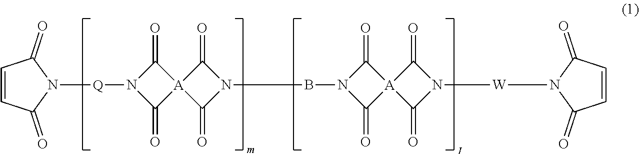

wherein A independently represents a tetravalent organic group having a cyclic structure, B independently represents a divalent hydrocarbon group having 6 to 200 carbon atoms, Q independently represents a divalent alicyclic hydrocarbon group having 6 to 60 carbon atoms, W is B or Q, at least one of B and W is a dimer acid frame-derived hydrocarbon group, l is 1 to 100, m is 1 to 200, no restrictions are imposed on an order of each repeating unit identified by m and l, and a bonding pattern may be alternate, block or random; the formula (3) being expressed as

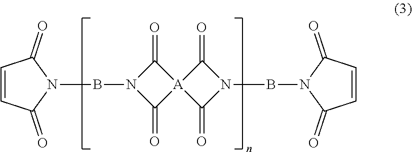

wherein A independently represents a tetravalent organic group having a cyclic structure, B independently represents a divalent hydrocarbon group having 6 to 200 carbon atoms, at least one B represents a dimer acid frame-derived hydrocarbon group, and n is 0 to 100.

[3]

The heat-curable maleimide resin composition according to [2], wherein A in the formulae (1) and (3) is any one of the tetravalent organic groups represented by the following structural formulae

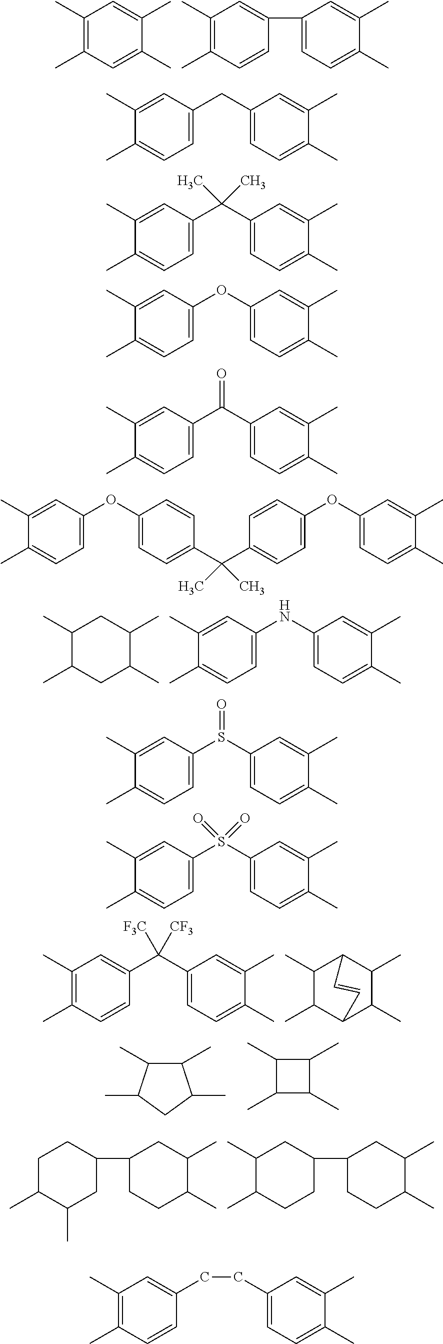

[4]

The heat-curable maleimide resin composition according to any one of [1] to [3], wherein a ratio of change of the dielectric tangent of the cured product at 40 GHz to the dielectric tangent thereof at 10 GHz is not higher than +/−30%.

[5]

The heat-curable maleimide resin composition according to [1], wherein the reaction initiator as the component (B) is (B1) an organic peroxide having a one-hour half-life temperature of not lower than 140° C.

[6]

The heat-curable maleimide resin composition according to [5], further comprising a polymerization inhibitor as a component (C).

[7]

An uncured film for substrate formation comprising the heat-curable maleimide resin composition according to any one of [1] to [6].

[8]

A cured film for substrate formation comprising the cured product of the heat-curable maleimide resin composition according to any one of [1] to [6].

[9]

A prepreg comprising the heat-curable maleimide resin composition according to any one of [1] to [6] and a fiber base material.

[10]

A laminate comprising the cured product of the heat-curable maleimide resin composition according to any one of [1] to [6].

[11]

A printed-wiring board comprising the cured product of the heat-curable maleimide resin composition according to any one of [1] to [6].

The heat-curable maleimide resin composition of the present invention yields a cured product having excellent dielectric properties even in the high-frequency region, a low water absorption rate, and a high Tg. Further, one embodiment of the present invention also exhibits an excellent moldability and embedding property.

Thus, the heat-curable maleimide resin composition of the present invention is suitable for use in an uncured/cured film, particularly an uncured/cured film for substrate formation, a prepreg, a laminate and a printed-wiring board.

### BRIEF DESCRIPTION OF THE DRAWINGS

FIG. 1 shows a cut end surface of one example of a prepreg of the present invention.

FIG. 2 shows a cut end surface of one example of a laminate of the present invention.

FIG. 3 shows a cut end surface of one example of a printed-wiring board of the present invention.

FIG. 4A shows a cut end surface of a copper-clad laminate for evaluation that was used for transmission loss measurement.

FIG. 4B shows a top view of the copper-clad laminate for evaluation that was used for transmission loss measurement.

FIG. 5 shows a cut end surface of a molded substrate whose tetrafluoroethylene-ethylene copolymer resin film has been removed.

### DETAILED DESCRIPTION OF THE INVENTION

The present invention is described in greater detail hereunder.

### (A) Maleimide Compound Having at Least One Dimer Acid Frame-Derived Hydrocarbon Group Per Molecule

A component (A) used in the present invention is a maleimide compound having at least one dimer acid frame-derived hydrocarbon group per molecule; the composition of the present invention contains two or more kinds of such maleimide compounds.

A dimer acid here refers to a liquid dibasic acid whose main component is a dicarboxylic acid having 36 carbon atoms, which is produced by dimerizing an unsaturated fatty acid having 18 carbon atoms and employing a natural substance such as a vegetable fat or oil as its raw material; a dimer acid may contain multiple structures as opposed to one single type of frame, and there exist several types of isomers. Typical dimer acids are categorized under the names of (a) linear type, (b) monocyclic type, (c) aromatic ring type, and (d) polycyclic type.

In this specification, a dimer acid frame refers to a group induced from a dimer diamine having a structure established by substituting the carboxy groups in such dimer acid with primary aminomethyl groups. That is, as a dimer acid frame, it is preferred that the component (A) have a group obtained by substituting the two carboxy groups in any of the following dimer acids (a) to (d) with methylene groups.

Further, as for the dimer acid frame-derived hydrocarbon group in the maleimide compound as the component (A), more preferred from the perspectives of heat resistance and reliability of a cured product are those having a structure with a reduced number of carbon-carbon double bonds in the dimer acid frame-derived hydrocarbon group due to a hydrogenation reaction.

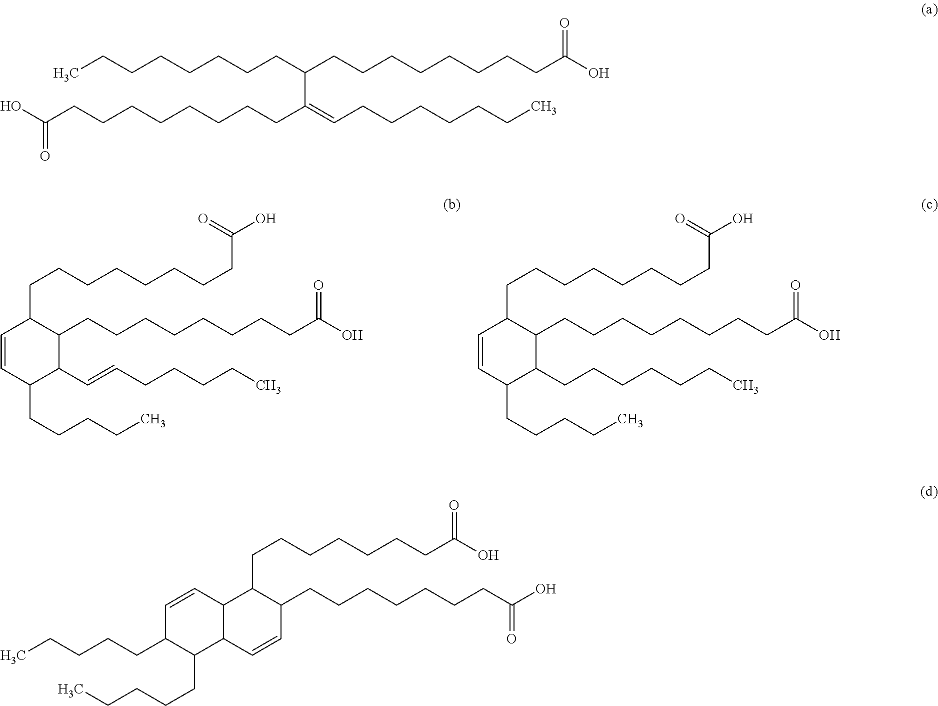 [SMILES: CCCCCCC/C=C(/CCCCCCCCC(=O)O)C(CCCCCCCC)CCCCCCCCC(=O)O ; CCCCC/C=C/C1C(CCCCC)C=CC(CCCCCCCCC(=O)O)C1CCCCCCCCC(=O)O ; CCCCCCCC1C(CCCCC)C=CC(CCCCCCCCC(=O)O)C1CCCCCCCCC(=O)O ; CCCCCC1C=CC2C(C=CC(CCCCCCCC(=O)O)C2CCCCCCCC(=O)O)C1CCCCC]

It is preferred that one kind of the component (A) be a maleimide compound (A-1) represented by the following formula (1), and that an other kind thereof be a maleimide compound (A-2) represented by the following formula (3).

### (A-1)

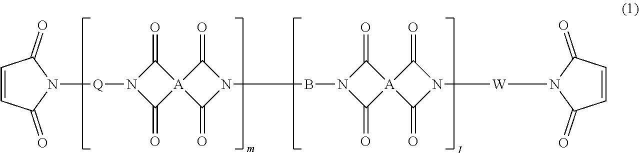

In the formula (1), A independently represents a tetravalent organic group having a cyclic structure; B independently represents a divalent hydrocarbon group having 6 to 200 carbon atoms; Q independently represents a divalent alicyclic hydrocarbon group having 6 to 60 carbon atoms; W is B or Q; at least one of B and W is a dimer acid frame-derived hydrocarbon group; l is 1 to 100; and m is 1 to 200. There are no restrictions imposed on the order of each repeating unit identified by m and l; the bonding pattern may be alternate, block or random.

If using the maleimide compound (A-1) represented by the formula (1), as compared to when using a general maleimide compound having many aromatic rings, the composition both before and after curing will have a high reliability in that the composition will exhibit superior dielectric properties, a strong adhesion force to a metal foil such as a copper foil, and a high Tg for a composition containing a dimer acid frame-containing maleimide compound. One kind of the maleimide compound represented by the formula (1) may be used alone, or two or more kinds thereof may be used in combination.

Further, in the formula (1), A independently represents a tetravalent organic group having a cyclic structure; particularly, it is preferred that A be any one of the tetravalent organic groups represented by the following structural formulae.

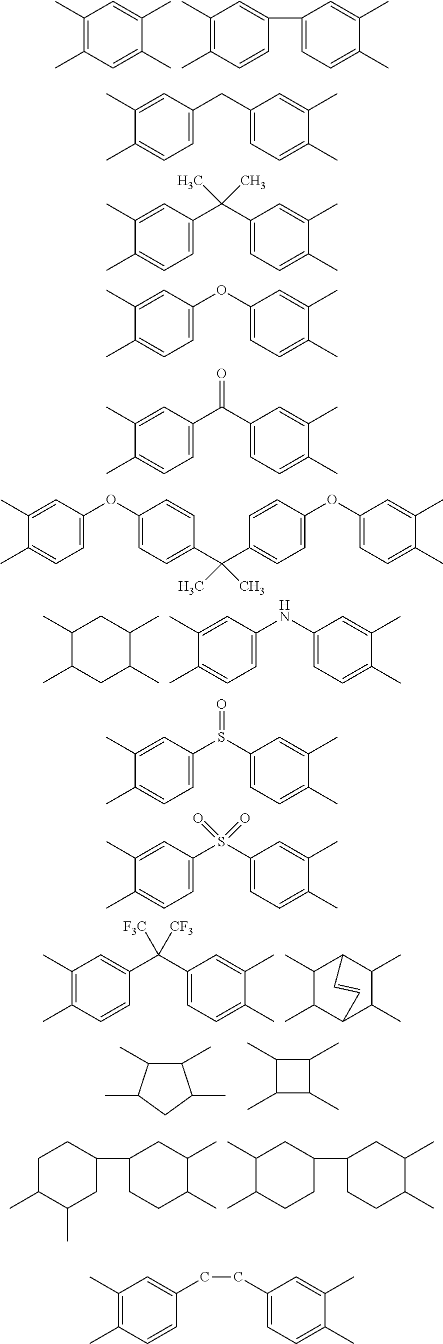

In the above formulae, bonds that are yet unbonded to substituent groups are to be bonded to carbonyl carbons forming cyclic imide structures in the formula (1).

Further, in the formula (1), B independently represents a divalent hydrocarbon group having 6 to 200, preferably 8 to 100, more preferably 10 to 50 carbon atoms. Particularly, it is preferred that this divalent hydrocarbon group be a branched divalent hydrocarbon group with at least one of the hydrogen atoms in the aforementioned divalent hydrocarbon group being substituted by an alkyl group or alkenyl group having 6 to 200, preferably 8 to 100, more preferably 10 to 50 carbon atoms. The branched divalent hydrocarbon group may be any of a saturated aliphatic hydrocarbon group and an unsaturated hydrocarbon group, and may have an alicyclic structure or an aromatic ring structure in the midway of the molecular chain.

One specific example of such branched divalent hydrocarbon group may be a divalent hydrocarbon group derived from a dual-end diamine called dimer diamine. Thus, it is particularly preferred that B have a group obtained by substituting each of the two carboxy groups in any of the above dimer acids (a) to (d) with a methylene group.

Further, in the formula (1), Q independently represents a divalent alicyclic hydrocarbon group having 6 to 60 carbon atoms, preferably a divalent alicyclic hydrocarbon group having 6 to 30 carbon atoms, more preferably an alicyclic hydrocarbon group having 6 to 20 carbon atoms, even more preferably an alicyclic hydrocarbon group having 8 to 18 carbon atoms. As such alicyclic hydrocarbon group, preferred are those having a cyclohexane frame; as a group having such cyclohexane frame, there may be employed a group having one cyclohexane ring, such as that expressed by the following formula (2); or a polycyclic group with multiple cyclohexane rings being either bonded together via alkylene group(s) or bridged.

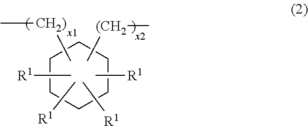

In the formula (2), R¹ independently represents a hydrogen atom or an alkyl group having 1 to 5 carbon atoms; x1 and x2 each independently represent a number of 0 to 4.

Here, specific examples of R¹ include a hydrogen atom, a methyl group, an ethyl group, an n-propyl group, an isopropyl group, an n-butyl group, an isobutyl group and a t-butyl group. Particularly, a hydrogen atom and a methyl group are preferred. Here, R's may be identical to or different from one another.

Further, x1 and x2 each independently represent a number of 0 to 4, preferably a number of 0 to 2. Here, x1 and x2 may be identical to or different from each other.

Specific examples of Q include the divalent alicyclic hydrocarbon groups represented by the following structural formulae.

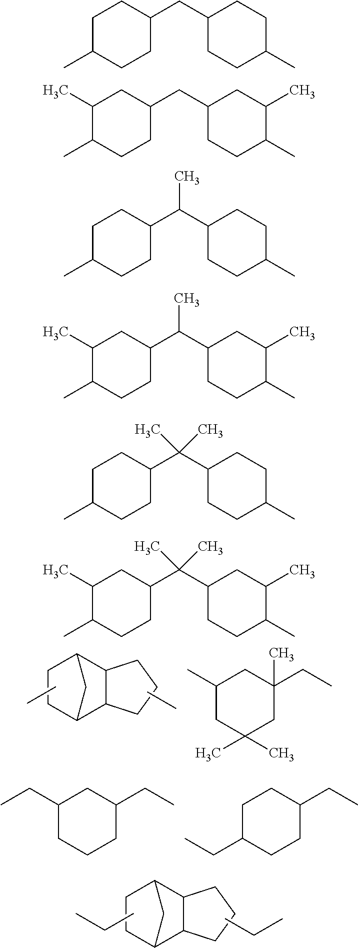

In the above formulae, bonds that are yet unbonded to substituent groups are to be bonded to nitrogen atoms forming cyclic imide structures in the formula (1).

In the formula (1), W is B or Q. As for W, a difference in production method determines whether it is a structural unit having B or Q.

In the formula (1), 1 is 1 to 100, preferably 1 to 60, more preferably 2 to 50; m is 1 to 200, preferably 1 to 50, more preferably 3 to 40. Extremely large values of m and l may lead to an impaired fluidity and a poor moldability. There are no restrictions on the order of each repeating unit identified by m and l; the bonding pattern may be alternate, block or random. A block pattern is preferred in terms of easiness in achieving a higher Tg.

### (A-2)

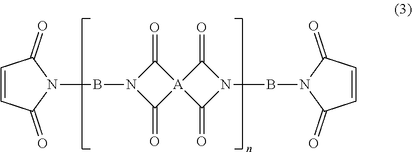

In the formula (3), A, as is the case with the formula (1), independently represents a tetravalent organic group having a cyclic structure; B independently represents a divalent hydrocarbon group having 6 to 200 carbon atoms, where at least one B represents a dimer acid frame-derived hydrocarbon group. n is 0 to 100.

If using the maleimide compound (A-2) represented by the formula (3), as compared to when using a general maleimide compound having many aromatic rings, the composition both before and after curing will be superior in that it will exhibit excellent dielectric properties, where in particular, the usage of such maleimide compound is not only effective in maintaining dielectric properties even in the high-frequency region, but also leads to a stronger adhesion force to a copper foil as compared to when using the maleimide compound represented by the formula (1) alone. One kind of the maleimide compound represented by the formula (3) may be used alone, or two or more kinds thereof may be used in combination.

In the formula (3), A, as is the case with A in the formula (1), independently represents a tetravalent organic group having a cyclic structure; particularly, it is preferred that A be any one of the tetravalent organic groups represented by the following formulae.

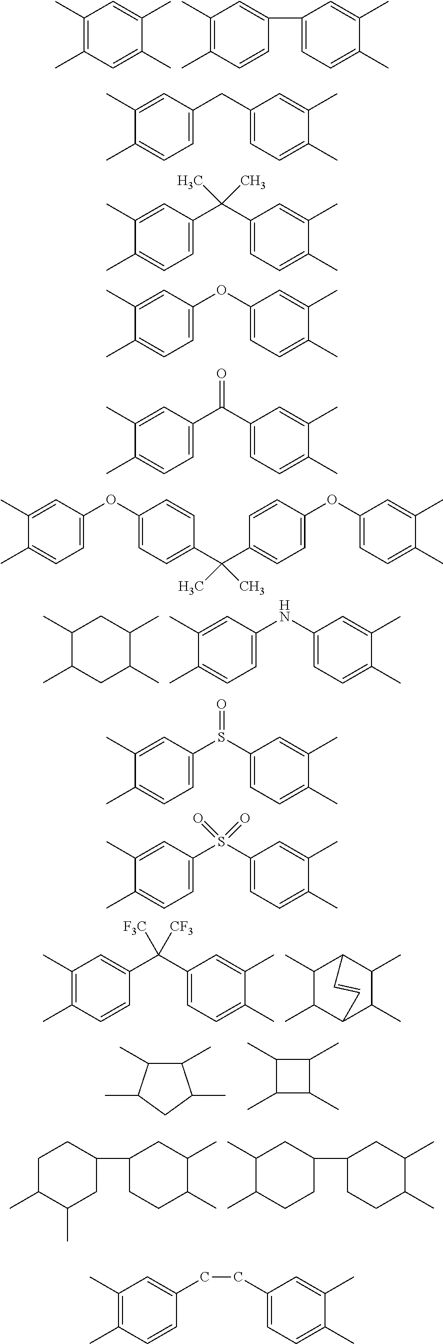

In the above formulae, bonds that are yet unbonded to substituent groups are to be bonded to carbonyl carbons forming cyclic imide structures in the formula (3).

Further, in the formula (3), B independently represents a divalent hydrocarbon group having 6 to 200, preferably 8 to 100, more preferably 10 to 50 carbon atoms, where at least one B represents a dimer acid frame-derived hydrocarbon group, and as a dimer acid frame, it is preferred that there be contained a group obtained by substituting the two carboxy groups in any of the above dimer acids (a) to (d) with methylene groups. Similarly, it is preferred that this divalent hydrocarbon group be a branched divalent hydrocarbon group with at least one of the hydrogen atoms in the aforementioned divalent hydrocarbon group being substituted by an alkyl group or alkenyl group having 6 to 200, preferably 8 to 100, more preferably 10 to 50 carbon atoms. The branched divalent hydrocarbon group may be any of a saturated aliphatic hydrocarbon group and an unsaturated hydrocarbon group, and may have an alicyclic structure or an aromatic ring structure in the midway of the molecular chain.

In the formula (3), n is 0 to 100, preferably 0 to 60, more preferably 0 to 50. An extremely large value of n may lead to an impaired solubility and fluidity as well as a poor moldability.

There are no particular restrictions on the number average molecular weight of each of the two maleimide compounds ((A-1) and (A-2)) as the component (A); in terms of handling property of the composition, the number average molecular weight is preferably 800 to 50,000, more preferably 900 to 30,000. Further, the component (A) may contain a maleimide compound(s) other than (A-1) and (A-2).

Here, the number average molecular weight mentioned in the present invention refers to a number average molecular weight that is measured by gel permeation chromatography (GPC) under the following measurement conditions, using polystyrene as a reference substance.

[Measurement conditions]
Developing solvent: Tetrahydrofuran (THF)
Flow rate: 0.35 mL/min
Detector: Differential refractive index detector (RI)

### Column: TSK Guardcolumn Super H-L

TSK gel Super HZ4000 (4.6 mm I.D.×15 cm×1)
TSK gel Super HZ3000 (4.6 mm I.D.×15 cm×1)
TSK gel Super HZ2000 (4.6 mm I.D.×15 cm×2)
(All manufactured by Tosoh Corporation)
Column temperature: 40° C.
Sample injection volume: 5 μL (THF solution with a concentration of 0.2% by mass)

There are no particular restrictions on the amount of the two kinds of component (A) contained in the resin composition of the present invention; in terms of heat resistance and dimension stability of the cured product, if not adding a later-described inorganic filler, it is preferred that the two kinds of component (A) be contained in an amount of not smaller than 90% by mass but smaller than 100% by mass, more preferably 90 to 99% by mass, per a total of all components other than an organic solvent in a case where the composition is to be prepared as a varnish. If adding the later-described inorganic filler, it is preferred that the two kinds of component (A) be contained in an amount of 10 to 90% by mass, more preferably 20 to 80% by mass, per the total of all components other than the organic solvent in the case where the composition is to be prepared as a varnish.

Further, when both (A-1) and (A-2) are contained, it is preferred that a ratio by mass thereof be (A-1):(A-2)=95:5 to 40:60, more preferably (A-1):(A-2)=90:10 to 60:40.

### (B) Reaction Initiator

A reaction initiator as a component (B) is added to promote a cross-linking reaction of the maleimide compound as the component (A), and a reaction between the maleimide groups in the component (A) and reactive groups capable of reacting with them.

There are no particular restrictions on the component (B) so long as it is capable of promoting a cross-linking reaction, examples of which may include ion catalysts such as imidazoles, tertiary amines, quaternary ammonium salts, a boron trifluoride-amine complex, organophosphines, and an organophosphonium salt; organic peroxides such as diallyl peroxide, dialkyl peroxide, peroxide carbonate, and hydroperoxide; and radical polymerization initiators such as azoisobutyronitrile.

Among them, preferred are an organic peroxide and a radical polymerization initiator if the reaction initiator is to promote a reaction of the component (A) alone, or if the reactive groups in a later-described heat-curable resin which is not the component (A) and contains reactive groups capable of reacting with maleimide groups are carbon-carbon double bond-containing groups such as a maleimide group, an alkenyl group and a (meth)acryloyl group. Examples of the organic peroxide include dicumyl peroxide, t-butyl peroxybenzoate, t-amyl peroxybenzoate, dibenzoyl peroxide, and dilauroyl peroxide.

Further, basic compounds such as imidazoles and tertiary amines are preferred if the reactive groups in the heat-curable resin which is not the component (A) and contains reactive groups capable of reacting with maleimide groups are an epoxy group, a hydroxyl group or an acid anhydride group. While it is also possible to use imidazole or amines for homopolymerization of maleimide groups, attentions are required as, for example, the usage of imidazole requires an extremely high temperature, and the usage of amines tends to result in an extremely short pot life.

In one mode of the present invention, if using, as the reaction initiator as the component (B), (B1) an organic peroxide having a one-hour half-life temperature of not lower than 140° C., the composition will have an excellent moldability (flow property) and embedding property. Examples of such organic peroxide having a one-hour half-life temperature of not lower than 140° C. include di-(t-butylperoxyisopropyl)benzene, di-t-butyl peroxide, cumyl hydroperoxide, t-butyl hydroperoxide and t-butyl cumyl peroxide.

It is preferred that the reaction initiator be added in an amount of 0.05 to 10 parts by mass, more preferably 0.1 to 5 parts by mass, per 100 parts by mass of the component (A). Further, if adding the later-described other heat-curable resin to the composition, it is preferred that the reaction initiator be added in an amount of 0.05 to 10 parts by mass, particularly preferably 0.1 to 5 parts by mass, per a total of 100 parts by mass of the component (A) and such other heat-curable resin component. It is not preferable if the amount of the reaction initiator is out of the above ranges, because curing may take place in an extremely slow or fast manner when molding the maleimide resin composition. Further, the cured product obtained may also exhibit a poor balance between the heat resistance and moisture resistance thereof.

One kind of such reaction initiator as the component (B) may be used alone, or two or more kinds thereof may be used in combination.

The dielectric tangent of the cured product of the heat-curable maleimide resin composition of the present invention that contains the components (A) and (B) is not larger than 0.003 both at 10 GHz and 40 GHz. Dielectric tangent can also be lowered by adding an inorganic filler as typified by silica with a low dielectric tangent; however, it has now become clear that it is significantly important to lower the dielectric tangents of resin components such as the components (A) and (B), and that it shall strongly and especially affect the transmission loss in the millimeterwave region. Particularly, it is preferred that the dielectric tangent at 10 GHz and 40 GHz be not larger than 0.0025. Further, in terms of ease in circuit design or the like, it is preferred that a ratio of change of the dielectric tangent of the cured product at 40 GHz to the dielectric tangent thereof at 10 GHz be not higher than +/−30%, more preferably not higher than +/−25%. That is, as such ratio of change, it is preferred that a value of [(dielectric tangent at 40 GHz−dielectric tangent at 10 GHz)/dielectric tangent at 10 GHz×100] be −30% to +30%, more preferably −25% to +25%.

### Other Additives

If necessary, the heat-curable maleimide resin composition of the present invention may further contain various additives on the premise that the effects of the present invention will not be impaired. These additives are exemplified below.

### (C) Polymerization Inhibitor

The heat-curable maleimide resin composition of the present invention may further contain a polymerization inhibitor as a component (C). The polymerization inhibitor is added to improve the storage stability of the heat-curable maleimide resin composition of the present invention, or highly control reactivity; there are no particular restrictions on such polymerization inhibitor so long as it is effective. Particularly, if using, as the reaction initiator as the component (B), (B1) the organic peroxide having a one-hour half-life temperature of not lower than 140° C., it is preferred that the polymerization inhibitor as the component (C) also be added.

Examples of the polymerization inhibitor include those that are generally and often used, such as catechol, resorcinol and 1,4-hydroquinone, and also include alkylcatechol-based compounds such as 2-methylcatechol, 3-methylcatechol, 4-methylcatechol, 2-ethylcatechol, 3-ethylcatechol, 4-ethylcatechol, 2-propylcatechol, 3-propylcatechol, 4-propylcatechol, 2-n-butyl catechol, 3-n-butylcatechol, 4-n-butylcatechol, 2-tert-butylcatechol, 3-tert-butylcatechol, 4-tert-butylcatechol, and 3,5-di-tert-butylcatechol; alkylresorcinol-based compounds such as 2-methylresorcinol, 4-methylresorcinol, 2-ethylresorcinol, 4-ethylresorcinol, 2-propylresorcinol, 4-propylresorcinol, 2-n-butylresorcinol, 4-n-butylresorcinol, 2-tert-butylresorcinol, and 4-tert-butylresorcinol; alkylhydroquinone-based compounds such as methylhydroquinone, ethylhydroquinone, propylhydroquinone, and tert-butylhydroquinone; phosphine compounds such as tributylphosphine, trioctylphosphine, tricyclohexylphosphine, and triphenylphosphine; phosphine oxide compounds such as trioctylphosphine oxide and triphenylphosphine oxide; phosphite compounds such as triphenylphosphite and trisnonylphenylphosphite; hindered amine-based compounds such as 2,2,6,6-tetramethylpiperidine-1-oxyl and 4-hydroxy-2,2,6,6-tetramethylpiperidine-1-oxyl; naphthalene compounds such as 1,4-dihydroxy-2-naphthalenesulfonic acid ammonium salt and 4-methoxy-1-naphthol; naphthoquinone compounds such as 1,4-naphthoquinone, 2-hydroxy-1,4-naphthoquinone, and anthrone; and phenolic antioxidants such as pyrogallol, phloroglucin, 2,6-di-t-butyl-p-cresol and 4,4′-butylidene-bis(6-tert-butyl-m-cresol).

It is preferred that the polymerization inhibitor as the component (C) be added in an amount of 0.01 to 0.50 parts by mass, more preferably 0.02 to 0.45 parts by mass, even more preferably 0.03 to 0.40 parts by mass, per 100 parts by mass of the component (A).

Further, if the composition of the present invention contains the later-described heat-curable maleimide resin which is not the component (A) and has reactive groups capable of reacting with maleimide groups, it is preferred that the polymerization inhibitor as the component (C) be added in an amount of 0.01 to 0.70 parts by mass, more preferably 0.02 to 0.60 parts by mass, even more preferably 0.03 to 0.50 parts by mass, per 100 parts by mass of the heat-curable maleimide resin components.

Further, one kind of the component (C) may be used alone, or two or more kinds thereof may be used together in a mixed manner.

Heat-Curable Resin Having Reactive Group Capable of Reacting with Maleimide Group

In the present invention, there may further be added a heat-curable resin having reactive groups capable of reacting with maleimide groups.

There are no restrictions on the type of such heat-curable resin, examples of which may include various resins other than the component (A), such as an epoxy resin, a phenolic resin, a melamine resin, a silicone resin, a cyclic imide resin as typified by a maleimide compound other than the component (A), a urea resin, a heat-curable polyimide resin, a modified polyphenylene ether resin, a heat-curable acrylic resin, and an epoxy-silicone hybrid resin. Further, examples of the reactive groups capable of reacting with maleimide groups include an epoxy group, a maleimide group, a hydroxyl group, an acid anhydride group, an alkenyl group such as an allyl group and a vinyl group, a (meth)acryloyl group, and a thiol group.

In terms of reactivity, it is preferred that the reactive group in the heat-curable resin be one selected from an epoxy group, a maleimide group, a hydroxyl group and an alkenyl group; and in terms of dielectric property, an alkenyl group or a (meth)acryloyl group are more preferred.

Here, the heat-curable resin having the reactive groups capable of reacting with maleimide groups is added in an amount of 0 to 60% by mass, preferably 0 to 50% by mass, per a sum total of the heat-curable resins.

### Inorganic Filler

In the present invention, there may further be added an inorganic filler if necessary. An inorganic filler is added to improve the strength and rigidity of the cured product of the heat-curable maleimide resin composition of the present invention, or adjust a thermal expansion coefficient and the dimension stability of the cured product. As such inorganic filler, there may be used those that are generally added to an epoxy resin composition or a silicone resin composition. There may be listed, for example, silicas such as a spherical silica, a molten silica and a crystalline silica; alumina; silicon nitride; aluminum nitride; boron nitride; barium sulfate; talc; clay; aluminum hydroxide; magnesium hydroxide; calcium carbonate; glass fibers; and glass particles. Further, for the sake of improving dielectric properties, there may also be used a fluorine-containing resin, a coating filler and/or hollow particles; and for the sake of for example imparting an electric conductivity, there may also be added metal particles, metal-coated inorganic particles, carbon fibers and carbon nanotubes. One kind of such inorganic filler may be used alone, or two or more kinds thereof may be used in combination. The inorganic filler may be added in an amount of 0 to 300 parts by mass, preferably 30 to 300 parts by mass, per 100 parts by mass of the component (A).

There are no particular restrictions on the average particle size and shape of the inorganic filler; if molding a film or a substrate, a spherical silica with an average particle size of 0.5 to 5 μm is particularly preferred. Here, an average particle size is a value obtained as a mass average value D₅₀ (or median size) in a particle size distribution measurement conducted by a laser diffraction method.

Further, for the sake of property improvement, it is preferred that the inorganic filler be one that has already been surface-treated with a silane coupling agent having organic groups capable of reacting with maleimide groups. Examples of such silane coupling agent include an epoxy group-containing alkoxysilane, an amino group-containing alkoxysilane, a (meth)acryloyl group-containing alkoxysilane, and an alkenyl group-containing alkoxysilane.

As such silane coupling agent, preferred are a (meth)acryloyl group- and/or an amino group-containing alkoxysilane, specific examples of which include 3-methacryloxypropyltrimethoxysilane, 3-acryloxypropyltrimethoxysilane, N-phenyl-3-aminopropyltrimethoxysilane, N-2-(aminoethyl)-3-aminopropyltrimethoxysilane, and 3-aminopropyltrimethoxysilane.

### Others

In addition to the above additives, there may also be added, for example, a non-functional silicone oil, a reactive diluent, a thermoplastic resin, a thermoplastic elastomer, an organic synthetic rubber, a photosensitizer, a light stabilizer, a flame retardant, a pigment, a dye, an adhesion aid and an ion-trapping agent.

Further, the above silane coupling agents such as an epoxy group-containing alkoxysilane, an amino group-containing alkoxysilane, a (meth)acryloyl group-containing alkoxysilane and an alkenyl group-containing alkoxysilane that are used for surface-treating the inorganic filler, may be separately added to the heat-curable maleimide resin composition of the present invention, and specific examples thereof may be ones that are similar to those listed above.

The heat-curable maleimide resin composition of the present invention may also be handled as a varnish after being dissolved into an organic solvent. By turning the composition into a varnish, a film can be formed easily, and a fiber base material such as a glass cloth made of an E glass, a low-dielectric glass, a quartz glass or the like can be easily coated and impregnated therewith. There are no restrictions on the organic solvent so long as it is capable of dissolving the components (A) and (B) as well as the heat-curable resin, as one of the other additives, that has reactive groups capable of reacting with maleimide groups; there may be listed, for example, anisole, tetralin, mesitylene, xylene, toluene, methyl ethyl ketone (MEK), tetrahydrofuran (THF), dimethylformamide (DMF), dimethyl sulfoxide (DMSO), and acetonitrile. Any one kind of them may be used alone, or two or more kinds thereof may be used in combination.

### Production Method

As a method for producing the heat-curable maleimide resin composition of the present invention, there may be employed, for example, a method where the components (A) and (B) as well as other additives that are added if necessary are to be mixed using a planetary mixer (by INOUE MFG., INC.) or a mixer “THINKY CONDITIONING MIXER” (by THINKY CORPORATION).

### Uncured Resin Film/Cured Resin Film

As for this heat-curable maleimide resin composition, an uncured resin sheet or an uncured resin film (also referred to as “uncured film” hereunder) can be obtained by applying the varnish to a base material and then volatilizing the organic solvent, and a cured resin sheet or a cured resin film (also referred to as “cured film” hereunder) can be obtained by further curing the uncured resin sheet or film. Examples of a method for producing the sheet and film include, but are not limited to those described below.

For example, after applying to a base material the heat-curable maleimide resin composition dissolved in the organic solvent (i.e. varnish), the organic solvent is eliminated by performing heating at a temperature of normally not lower than 80° C., preferably not lower than 100° C. for 0.5 to 20 min, and a strong cured maleimide resin film with a flat surface can then be formed by further performing heating at a temperature of not lower than 130° C., preferably not lower than 150° C. for 0.5 to 10 hours.

The temperature in the drying step for eliminating the organic solvent and the temperature in the subsequent heating and curing step may each be a constant temperature; it is preferred that these temperatures be raised in a step-wise manner. Thus, not only the organic solvent can be efficiently eliminated out of the composition, but the curing reaction of the resins can also take place efficiently.

Examples of a method for applying the varnish may include those employing a spin coater, a slit coater, a sprayer, a dip coater and a bar coater; there are no particular restrictions on such method.

As a base material, there may be used a general resin base material, examples of which include polyolefin resins such as a polyethylene (PE) resin, a polypropylene (PP) resin and a polystyrene (PS) resin; and polyester resins such as a polyethylene terephthalate (PET) resin, a polybutylene terephthalate (PBT) resin and a polycarbonate (PC) resin. The surface of such base material may also be subjected to a mold release treatment. Further, there are no particular restrictions on the thickness of a coating layer; a thickness after distilling away the solvent is 1 to 100 μm, preferably 3 to 80 μm. A cover film may also be provided on such coating layer.

Instead, the uncured film or cured film may also be produced by previously and preliminarily mixing the components, and then extruding the mixture into the shape of a sheet or a film with a melt-kneading machine.

The cured film obtained by curing the heat-curable maleimide resin composition of the present invention is not only superior in heat resistance, mechanical properties, electric properties, adhesiveness to base materials and solvent resistance, but also has a low relative permittivity. Thus, the composition of the invention can be applied to, for example, a passivation film or protective film for use in a semiconductor device, specifically those provided on the surface of a semiconductor element; a junction protective film for use in the junctions of a diode, a transistor or the like; an α-ray shielding film or interlayer insulating film for use in a VLSI; and an ion implantation mask. Moreover, the composition of the invention may also be applied to a conformal coating of a printed-circuit board, an oriented film of a liquid crystal surface element, a protective film of glass fibers, and a surface protective film of a solar cell. Further, the composition of the invention may be applied to a wide range of uses such as a paste composition including, for example, a paste composition for printing with an inorganic filler being added to the above heat-curable maleimide resin composition, and an electrically conductive paste composition with an electrically conductive filler being added to such resin composition.

Further, since the composition of the present invention can be turned into the shape of a film or a sheet in an uncured state, has a self-adhesiveness and is also superior in dielectric properties, the film of such composition is particularly suitable for use as an uncured film or cured film for substrate formation, such as a build-up film for a rigid substrate or the like, and a bonding film for a flexible printed-wiring circuit board (FPC) or the like. Further, the cured resin film may also be used as a coverlay film.

Instead, a fiber base material such as a glass cloth made of an E glass, a low-dielectric glass, a quartz glass or the like may be impregnated with the heat-curable maleimide resin composition that has been turned into a varnish, followed by eliminating the organic solvent to achieve a semi-cured state, thereby allowing the product thus obtained to be used as a prepreg. Further, a laminate or printed-wiring board including multilayered ones can be produced by laminating such prepreg and a copper foil or the like.

### Prepreg

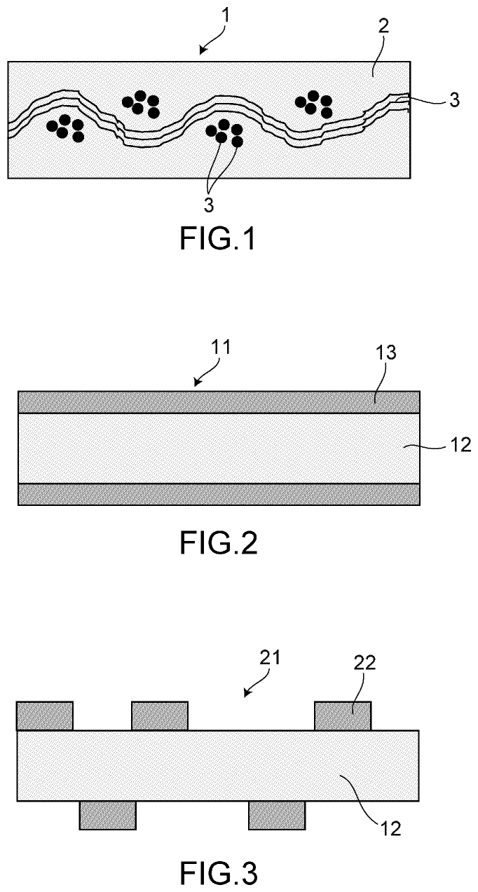

FIG. 1 shows a cut end surface of a prepreg of one embodiment of the present invention. A prepreg 1 has a heat-curable maleimide resin composition 2 and a fiber base material 3. The heat-curable maleimide resin composition 2 is ether the above heat-curable maleimide resin composition or a semi-cured product of such resin composition.

Here, a semi-cured product refers to a product of a state where the resin composition has been incompletely cured to the extent that the composition can actually be further cured. That is, the semi-cured product is a product of a state where the resin composition has been semi-cured i.e. a B-staged product. Meanwhile, an uncured state may also be referred to as A-stage. That is, the heat-curable maleimide resin composition 2 may be the heat-curable maleimide resin composition in the state of A-stage, or the heat-curable maleimide resin composition in the state of B-stage.

As described above, the fiber base material 3 may for example be an E glass, a low-dielectric glass, a quartz glass, or even an S glass or T glass; while there may be employed any type of glass, a quartz glass cloth having low dielectric properties is preferred in terms of taking advantage of the properties of a heat-curable maleimide resin composition. Here, the thickness of a generally used fiber base material is, for example, not smaller than 0.01 mm and not larger than 0.3 mm.

When producing the prepreg 1, it is preferred that the heat-curable maleimide resin composition 2 be a resin varnish prepared in the form of a varnish, because the fiber base material 3 as a base material for forming the prepreg is to be impregnated with the resin composition. Such resin composition in the form of a varnish (i.e. resin varnish) may for example be prepared as follows.

At first, components in the composition of the resin composition that are soluble in the organic solvent are to be added to the organic solvent to dissolve them. At that time, heating may also be performed if necessary. Next, components that are insoluble in the organic solvent, such as the inorganic filler used as needed are added, followed by using a ball mill, a bead mill, a planetary mixer, a roll mill or the like to disperse them until a given dispersed state has been reached, thereby obtaining the resin composition in the form of a varnish (i.e. resin varnish). There are no particular restrictions on the organic solvent used here so long as the organic solvent employed does not inhibit the curing reaction. Specific examples thereof include toluene, methyl ethyl ketone (MEK), xylene and anisole.

As a method for producing the prepreg 1, there may be employed, for example, a method where the fiber base material 3 is at first impregnated with the heat-curable maleimide resin composition 2 e.g. the heat-curable maleimide resin composition 2 prepared in the form of a varnish, and is then dried. The fiber base material 3 is to be impregnated with the heat-curable maleimide resin composition 2 by, for example, dipping the fiber base material 3 into the resin composition, or applying the resin composition to the fiber base material 3. If necessary, the fiber base material 3 may be repeatedly impregnated several times. Further, at that time, it is also possible to repeat impregnation using multiple resin compositions with different compositions and concentrations, whereby the composition and impregnation amount can eventually be adjusted to desired ones. The fiber base material 3 impregnated with the heat-curable maleimide resin composition (resin varnish) 2 is to be heated under a desired heating condition(s) e.g. at 80 to 180° C. for 1 to 20 min. By heating, there can be obtained a prepreg 1 having an uncured (A-staged) or semi-cured (B-staged) heat-curable maleimide resin composition 2. Here, heating performed in the above manner will volatilize the organic solvent from the resin varnish whereby the organic solvent will be able to be reduced or eliminated.

### Laminate

A laminate of one embodiment of the present invention is one prepared by laminating an insulating layer containing or consisting of the cured product of the heat-curable maleimide resin composition; and a layer other than the insulating layer. A generally well-known laminate is a metal-clad laminate; FIG. 2 shows a cut end surface thereof. A metal-clad laminate 11 has an insulating layer 12 containing or consisting of the cured product of the heat-curable maleimide resin composition; and a metal foil 13 arranged on both surfaces of the insulating layer 12. Shown in FIG. 2 is a double-sided metal-clad laminate with the metal foil 13 being provided on both surfaces of the insulating layer 12; the metal-clad laminate may also be a single-sided metal-clad laminate with the metal foil 13 being provided only on one surface of the insulating layer 12.

Further, the insulating layer 12 may be a layer consisting of the cured product of the heat-curable maleimide resin composition, a layer consisting of the cured product of the prepreg 1, or even a layer with multiple pieces of the cured product of the prepreg 1 being laminated together. Further, there are no particular restrictions on the thickness of the metal foil 13; this thickness varies depending on, for example, the performance required for a wiring board that is eventually manufactured. The thickness of the metal foil 13 may be appropriately determined depending on a desired purpose; for example, a thickness of 1 to 70 μm is preferred. Further, the metal foil 13 may for example be a copper foil, an aluminum foil or the like; if the metal foil is thin, there may be employed a carrier-attached copper foil having a release layer and a carrier, for the purpose of improving handling property.

There are no particular restrictions on a method for producing such laminate so long as the method used is a general method. For example, if using the prepreg, there may be employed a method where the laminate is produced in such a manner that one or multiple pieces of the prepreg 1 (FIG. 1) are to be stacked together, and the metal foil 13 such as a copper foil is then placed on one or both surfaces thereof in the vertical direction before performing heating and pressurization so as to mold them into an integrally laminated product.

### Printed-Wiring Board

A printed-wiring board of one embodiment of the present invention is one containing the cured product of the heat-curable maleimide resin composition; as one example thereof, FIG. 3 shows a cut end surface of a printed-wiring board produced using the abovementioned laminate, particularly the metal-clad laminate shown in FIG. 2. As described above, the insulating layer 12 of the metal-clad laminate used in the production of a printed-wiring board may be one produced using the aforementioned prepreg. By known methods, a printed-wiring board 21 can be produced by performing a drilling processing, a metal plating processing, a circuit formation processing and a multilayer adhesion processing with respect to the metal-clad laminate 11, of which the circuit formation processing is realized by performing etching or the like on the metal foil.

### WORKING EXAMPLES

The present invention is described in detail hereunder with reference to working and comparative examples; the present invention shall not be limited to the following working examples.

Components used in the working and comparative examples are as follows.

### (A-1) Maleimide Compound

(A-1-1): Dimer acid frame-derived hydrocarbon group-containing bismaleimide compound represented by the following formula (BMI-2500 by Designer Molecules Inc.), number average molecular weight: 5000

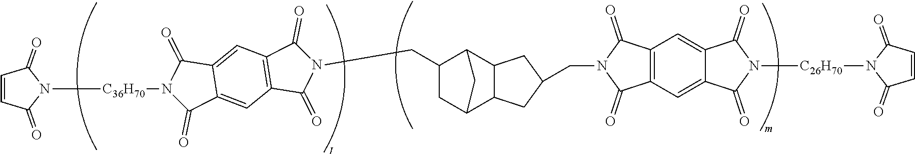

—C₃₆H₇₀— represents a dimer acid frame-derived structure.
m≈5 (Average value), l≈1 (Average value)

(A-1-2): Dimer acid frame-derived hydrocarbon group-containing bismaleimide compound represented by the following formula (SLK-2600 by Shin-Etsu Chemical Co., Ltd.), number average molecular weight: 6000

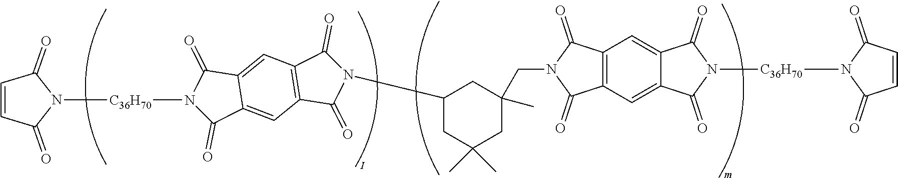

—C₃₆H₇₀— represents a dimer acid frame-derived structure.
m≈5 (Average value), l≈1 (Average value)

### (A-2) Maleimide Compound

(A-2-1): Dimer acid frame-derived hydrocarbon group-containing bismaleimide compound represented by the following formula (BMI-1400 by Designer Molecules Inc.), number average molecular weight: 1700

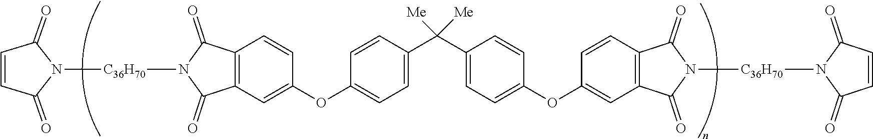

—C₃₆H₇₀— represents a dimer acid frame-derived structure.
n≈2 (Average value)

(A-2-2): Dimer acid frame-derived hydrocarbon group-containing bismaleimide compound represented by the following formula (BMI-3000J by Designer Molecules Inc.), number average molecular weight: 5000

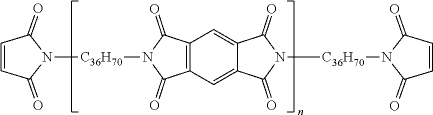

—C₃₆H₇₀— represents a dimer acid frame-derived structure.
n≈5 (Average value)

(A-2-3): Dimer acid frame-derived hydrocarbon group-containing bismaleimide compound represented by the following formula (BMI-1500 by Designer Molecules Inc.), number average molecular weight: 2200

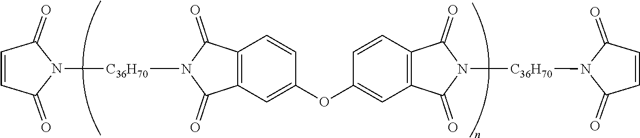

—C₃₆H₇₀— represents a dimer acid frame-derived structure.
n≈2

(A-2-4): Dimer acid frame-derived hydrocarbon group-containing bismaleimide compound represented by the following formula (BMI-5000 by Designer Molecules Inc.), number average molecular weight: 10000

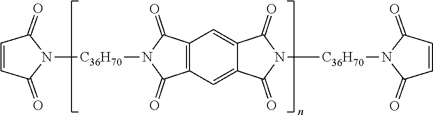

—C₃₆H₇₀— represents a dimer acid frame-derived structure.
n≈8

### (A-3) Maleimide Compound for Use in Comparative Example

(A-3-1): 1,6-bismaleimide-(2,2,4-trimethyl)hexane (BMI-TMH by Daiwakasei Industry Co., LTD.)

(A-3-2): 4,4′-diphenylmethanebismaleimide (BMI-1000 by Daiwakasei Industry Co., LTD.)

(A-3-3): Biphenyl aralkyl-type maleimide compound (MIR-3000 by Nippon Kayaku Co., Ltd.), number average molecular weight: 670

### (B) Reaction Initiator

(B-1): Dicumylperoxide (PERCUMYL D by NOF CORPORATION, one-hour half-life temperature 135.7° C.)

(B1-1): Di-t-butylperoxide (Trigonox B by KAYAKU NOURYON CORPORATION, one-hour half-life temperature 147° C.)

(B1-2): Di-(t-butylperoxyisopropyl)benzene (Perkadox 14S-FL by KAYAKU NOURYON CORPORATION, one-hour half-life temperature 141° C.)

(B-2): Dilauroyl peroxide (Laurox by KAYAKU NOURYON CORPORATION, one-hour half-life temperature 79° C.)

### (C) Polymerization Inhibitor

(C-1): 2,6-di-t-butyl-p-cresol (BHT SWANOX by Seiko Chemical Co, Ltd.) Inorganic filler

Spherical silica having an average particle size of 0.5 μm (SO-25R by ADMATECHS COMPANY LIMITED)

### Working Examples 1 to 8; Comparative Examples 1 to 12

A resin composition was produced as follows using (B-1) dicumylperoxide as the reaction initiator (B), and then evaluated.

### Preparation and Appearance of Varnish

At the compounding ratios shown in Tables 1 and 2, the components listed in Tables 1 and 2 were put into a 500 mL four-necked flask equipped with a Dimroth condenser and a stirrer, followed by stirring them at 50° C. for two hours to obtain a varnish-like resin composition. The appearance of the varnish-like resin composition was then visually observed and evaluated, where ◯ was given to examples in which the varnish was transparent, A was given to examples in which the varnish exhibited turbidity, but no separation, and x was given to examples in which the varnish totally exhibited separation; the evaluation results thereof are shown in Tables 1 and 2. Here, no further evaluation was performed on the examples where the appearance of the varnish was evaluated as x. However, as for examples containing the inorganic filler, since visual observation was not possible due to the inorganic filler, the appearance of the varnish was not evaluated, and these examples were marked “-” in Tables 1 and 2.

### Preparation of Uncured and Cured Film

After preparing the varnish by the above procedure, the varnish-like heat-curable maleimide resin compositions of the working examples 1 to 8 and comparative examples 1 to 8 and 10 to 12 exhibiting no separation in the varnish, were each applied to a 38 μm thick PET film with a roller coater, followed by drying them at 120° C. for 10 min to obtain a 50 μm thick uncured resin film. This uncured resin film was then placed on a 100 μm thick tetrafluoroethylene-ethylene copolymer resin film (AFLEX by AGC Inc.), followed by curing it under a condition of 180° C. for two hours to obtain a cured resin film.

### Relative Permittivity and Dielectric Tangent

A network analyzer (E5063-2D5 by Keysight Technologies) and a stripline (by KEYCOM Corporation) were connected to the cured resin film to measure a relative permittivity and dielectric tangent thereof at frequencies of 10 GHz and 40 GHz. Further, based on the measured results, calculations were made on how much the dielectric tangent at 40 GHz had changed from the dielectric tangent at 10 GHz.

### Glass-Transition Temperature

The glass-transition temperature (Tg) of the cured resin film was measured by DMA-800 manufactured by TA Instruments.

### Moisture Absorptivity

The cured resin film was cut out into a size of 80 mm×80 mm, and then left in a thermostatic bath of temperature 85° C., humidity 85% for 24 hours; a moisture absorptivity was then measured based on the weight of the film before and after absorbing moisture.

### Peeling Strength

A glass slide having a length of 75 mm, a width of 25 mm and a thickness of 1.0 mm was prepared; and a resin composition surface of the PET film-attached uncured film that had no such PET base material attached thereto was placed on one surface of the glass slide, followed by performing lamination at 100° C. and 0.3 MPa for 60 sec. After the lamination was over, the PET base material was peeled away, and an 18 μm thick copper foil (by MITSUI MINING & SMELTING CO., LTD., Rz: 0.6 μm) was then placed on the resin composition surface, followed by performing lamination at 100° C. and 0.3 MPa for 60 sec. After the lamination was over, curing was conducted under a condition of 180° C. for two hours to obtain an adhesion test piece.

For adhesiveness evaluation, there was measured a 90° peeling adhesion strength (kN/m) at the time of peeling the copper foil of each adhesion test piece away from the glass slide, at a temperature of 23° C. and a tension rate of 50 mm/min in accordance with JIS-C-6481 “Test methods of copper-clad laminates for printed wiring boards.”

### Preparation of Substrate for Evaluation; and Measurement of Transmission Loss

After impregnating a quartz glass cloth (SQX-2116C by Shin-Etsu Chemical Co., Ltd.) with each of the varnish-like resin compositions produced at the compounding ratios of the working examples 1 and 2 and the comparative examples 1, 2, 5, 6, 11 and 12, the quartz glass cloth was dried at 120° C. for 5 min to obtain a prepreg. At that time, adjustments were made so that the amount of the inorganic filler-containing heat-curable maleimide resin composition component contained therein (resin content) would be about 55% by mass.

Two pieces of prepreg were prepared in each example, where the two pieces of prepreg were stacked and laminated together, and an 18 μm thick copper foil (by MITSUI MINING & SMELTING CO., LTD., Rz: 0.6 μm) was further stacked on both surfaces thereof, followed by performing heating and pressurization at 180° C. and 3 MPa for two hours to obtain a copper-clad laminate for evaluation.

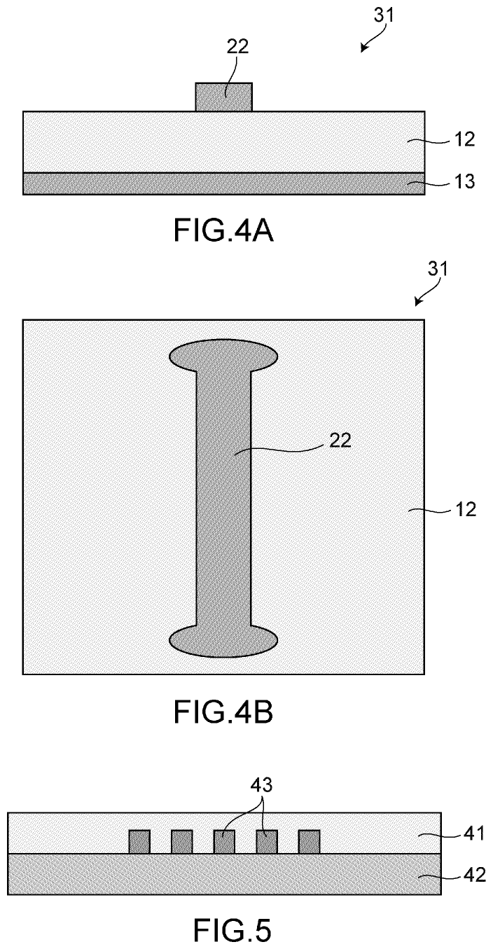

Next, the copper foil on one surface of the obtained copper-clad laminate for evaluation was subjected to etching to form a stripline having a length of 10 cm and a line width of 100 to 200 μm. FIGS. 4A and 4B respectively show a cut end surface and a top view of the copper-clad laminate for evaluation that was used for transmission loss measurement. The line width was selected so that an impedance would be 50Ω; a network analyzer (by Keysight Technologies) was used to measure transmission losses at 10 GHz and 40 GHz under an environment of temperature 25° C., humidity 50%. Here, in Tables 1 and 2, examples where such measurement was not conducted are marked “-.”

TABLE 1

| Composition compounding table | | | Working example | | | | | | | |
|---|---|---|---|---|---|---|---|---|---|---|
| (part by mass) | | | 1 | 2 | 3 | 4 | 5 | 6 | 7 | 8 |
| (A-1) | BMI-2500 | A-1-1 | 75.0 | 75.0 | 75.0 | | 60.0 | 75.0 | 90.0 | 50.0 |
| | SLK-2600 | A-1-2 | | | | 75.0 | | | | |
| (A-2) | BMI-1400 | A-2-1 | 25.0 | 25.0 | | 25.0 | 40.0 | 20.0 | 10.0 | |
| | BMI-3000J | A-2-2 | | | 25.0 | | | | | 50.0 |
| (A-3) | BMI-TMH | A-3-1 | | | | | | 5.0 | | |
| | BMI-1000 | A-3-2 | | | | | | | | |
| (B) | PERCUMYL D | B-1 | 1.0 | 1.0 | 1.0 | 1.0 | 1.0 | 1.0 | 1.0 | 1.0 |
| (Inorganic | SO-25R | | | 100.0 | | | | | | |
| filler) | | | | | | | | | | |
| (Solvent) | Cyclohexanone | | 100.0 | 100.0 | 100.0 | 100.0 | 100.0 | 100.0 | 100.0 | 100.0 |
| Evaluation | Varnish appearance | | ◯ | — | ◯ | ◯ | ◯ | Δ | ◯ | Δ |
| results | Relative permittivity at 10 GHz | | 2.52 | 2.96 | 2.49 | 2.48 | 2.41 | 2.61 | 2.61 | 2.43 |
| | Relative permittivity at 40 GHz | | 2.55 | 2.95 | 2.51 | 2.48 | 2.42 | 2.63 | 2.63 | 2.44 |
| | Dielectric tangent at 10 GHz | | 0.0019 | 0.0013 | 0.0018 | 0.0017 | 0.0022 | 0.0021 | 0.0020 | 0.0016 |
| | Dielectric tangent at 40 GHz | | 0.0021 | 0.0014 | 0.0018 | 0.0018 | 0.0022 | 0.0026 | 0.0023 | 0.0016 |
| | Ratio of change in dielectric | % | 11 | 8 | 0 | 6 | 0 | 24 | 15 | 0 |
| | tangent | | | | | | | | | |
| | Glass-transition temperature | ° C. | 136 | 135 | 141 | 140 | 107 | 162 | 143 | 101 |
| | Moisture absorptivity | % | 0.4 | 0.2 | 0.4 | 0.3 | 0.3 | 0.6 | 0.5 | 0.5 |
| | Peeling strength | kN/m | 1.2 | 0.9 | 1.2 | 1.3 | 1.4 | 0.9 | 0.7 | 1.4 |
| | Transmission loss at 10 GHz | dB | −1.1 | −1.1 | — | — | — | — | — | — |
| | Transmission loss at 40 GHz | dB | −3.0 | −2.4 | — | — | — | — | — | — |

TABLE 2

| Composition compounding table | | | Comparative example | | | | | |
|---|---|---|---|---|---|---|---|---|
| (part by mass) | | | 1 | 2 | 3 | 4 | 5 | 6 |
| (A-1) | BMI-2500 | A-1-1 | 100.0 | 100.0 | | | 75.0 | 75.0 |
| | SLK-2600 | A-1-2 | | | 100.0 | | | |
| (A-2) | BMI-1400 | A-2-1 | | | | | | |
| | BMI-3000J | A-2-2 | | | | 100.0 | | |
| (A-3) | BMI-TMH | A-3-1 | | | | | 25.0 | 25.0 |
| | BMI-1000 | A-3-2 | | | | | | |
| (B) | PERCUMYL D | B-1 | 1.0 | 1.0 | 1.0 | 1.0 | 1.0 | 1.0 |
| (Inorganic | SO-25R | | | 100.0 | | | | 100.0 |
| filler) | | | | | | | | |
| (Solvent) | Cyclohexanone | | 100.0 | 100.0 | 100.0 | 100.0 | 100.0 | 100.0 |
| Evaluation | Varnish appearance | | ◯ | — | ◯ | ◯ | Δ | — |
| results | Relative permittivity at 10 | | 2.63 | 3.02 | 2.56 | 2.43 | 2.65 | 3.02 |
| | Relative permittivity at 40 | | 2.61 | 3.02 | 2.53 | 2.42 | 2.72 | 3.05 |
| | Dielectric tangent at 10 GHz | | 0.0021 | 0.0016 | 0.0015 | 0.0015 | 0.0025 | 0.0018 |
| | Dielectric tangent at 40 GHz | | 0.0028 | 0.0020 | 0.0020 | 0.0015 | 0.0038 | 0.0026 |
| | Ratio of change in dielectric | % | 33 | 25 | 33 | 0 | 52 | 44 |
| | tangent | | | | | | | |
| | Glass-transition temperature | ° C. | 145 | 142 | 147 | 43 | 172 | 170 |
| | Moisture absorptivity | % | 0.3 | 0.2 | 0.4 | 0.2 | 1.4 | 0.9 |
| | Peeling strength | kN/m | 0.7 | 0.6 | 0.9 | 1.5 | 0.7 | 0.5 |
| | Transmission loss at 10 GHz | dB | −1.2 | −1.1 | — | — | −1.3 | −1.2 |
| | Transmission loss at 40 GHz | dB | −3.8 | −3.2 | — | — | −4.5 | −3.8 |
| Composition compounding table | | | Comparative example | | | | | |
| (part by mass) | | | 7 | 8 | 9 | 10 | 11 | 12 ** |
| (A-1) | BMI-2500 | A-1-1 | 75.0 | | | | | |
| | SLK-2600 | A-1-2 | | | | | | |
| (A-2) | BMI-1400 | A-2-1 | | | 25.0 | | | |
| | BMI-3000J | A-2-2 | | 75.0 | | | | |
| (A-3) | BMI-TMH | A-3-1 | | | | 100.0 | | |
| | BMI-1000 | A-3-2 | 25.0 | 25.0 | 75.0 | | 100.0 | 100.0 |
| (B) | PERCUMYL D | B-1 | 1.0 | 1.0 | 1.0 | 1.0 | 1.0 | 1.0 |
| (Inorganic | SO-25R | | | | | | | 100.0 |
| filler) | | | | | | | | |
| (Solvent) | Cyclohexanone | | 100.0 | 100.0 | 100.0 | 100.0 | 100.0 | 100.0 |
| Evaluation | Varnish appearance | | Δ | Δ | X | ◯ | ◯ | — |
| results | Relative permittivity at 10 | | 2.61 | 2.51 | Not | 2.71 | 3.16 | 3.34 |
| | Relative permittivity at 40 | | 2.61 | 2.58 | evaluated | 2.71 | 3.14 | 3.33 |
| | Dielectric tangent at 10 GHz | | 0.0035 | 0.0021 | | 0.0042 | 0.0150 | 0.0111 |
| | Dielectric tangent at 40 GHz | | 0.0046 | 0.0033 | | 0.0058 | 0.0178 | 0.0120 |
| | Ratio of change in dielectric | % | 31 | 57 | | 38 | 19 | 8 |
| | tangent | | | | | | | |
| | Glass-transition temperature | ° C. | 192 | 42/168* | | 210 | >250 | >250 |
| | Moisture absorptivity | % | 1.2 | 0.9 | | 1.9 | 1.3 | 1.0 |
| | Peeling strength | kN/m | 0.4 | 1.1 | | 0.9 | <0.3 | <0.3 |
| | Transmission loss at 10 GHz | dB | — | — | | — | −2.5 | −2.9 |
| | Transmission loss at 40 GHz | dB | — | — | | — | −13.8 | −11.9 |

*Two inflection points were observed in the glass-transition temperature measurement of the comparative example 8.
** In the comparative example 12, the prepreg was difficult to be handled, and there was exhibited an insufficient adhesion force to the copper foil, whereby the copper-clad laminate obtained had a poor appearance.

A resin composition was produced as follows using, as the reaction initiator (B), (B1) an organic peroxide having a one-hour half-life temperature of not lower than 140° C., and then evaluated.

### Working Examples 9 to 13; Comparative Examples 13 to 22

### Preparation and Appearance of Varnish

At the compounding ratios shown in Tables 3 and 4, the components listed in Tables 3 and 4 were put into a 500 mL four-necked flask equipped with a Dimroth condenser and a stirrer, followed by stirring them at 50° C. for two hours to obtain a varnish-like resin composition.

### Preparation of Uncured and Cured Film

After preparing the varnish by the above procedure, the varnish-like heat-curable maleimide resin compositions of the working examples 9 to 13 and comparative examples 13 to 22 exhibiting no separation in the varnish, were each applied to a 38 μm thick PET film with a roller coater, followed by drying them at 120° C. for 10 min to obtain a 50 μm thick uncured resin film. This uncured resin film was then placed on a 100 μm thick tetrafluoroethylene-ethylene copolymer resin film (AFLEX by AGC Inc.), followed by curing it under a condition of 180° C. for two hours to obtain a cured resin film.

### Relative Permittivity and Dielectric Tangent

A network analyzer (E5063-2D5 by Keysight Technologies) and a stripline (by KEYCOM Corporation) were connected to the cured resin film to measure a relative permittivity and dielectric tangent thereof at frequencies of 10 GHz and 40 GHz.

### Peeling Strength

A glass slide having a length of 75 mm, a width of 25 mm and a thickness of 1.0 mm was prepared; and a resin composition surface of the PET film-attached uncured film that had no such PET base material attached thereto was placed on one surface of the glass slide, followed by performing lamination at 100° C. and 0.3 MPa for 60 sec. After the lamination was over, the PET base material was peeled away, and an 18 μm thick copper foil (by MITSUI MINING & SMELTING CO., LTD., Rz: 0.6 μm) was then placed on the resin composition surface, followed by performing lamination at 100° C. and 0.3 MPa for 60 sec. After the lamination was over, curing was conducted under a condition of 180° C. for two hours to obtain an adhesion test piece.

For adhesiveness evaluation, there was measured a 90° peeling adhesion strength (kN/m) at the time of peeling the copper foil of each adhesion test piece away from the glass slide, at a temperature of 23° C. and a tension rate of 50 mm/min in accordance with JIS-C-6481 “Test methods of copper-clad laminates for printed wiring boards.”

### Moldability (Flow Property)

Two pieces of uncured film each having a size of 100 mm×100 mm×50 μm were stacked and laminated together, a copper foil having a size of 105 mm×105 mm×18 μm (by MITSUI MINING & SMELTING CO., LTD., Rz: 0.6 μm) was then stacked on both surfaces thereof, and a tetrafluoroethylene-ethylene copolymer resin film (AFLEX by AGC Inc.) was further stacked on the side of such copper foil that is not in contact with the uncured film, followed by performing molding at 180° C. and 3 MPa for two hours. There, ◯ was given to examples where the resin had flowed out by not more than 2 mm; Δ was given to examples where the resin had flowed out by more than 2 mm, but not more than 5 mm; □ was given to examples where the resin had flowed out by more than 5 mm, and x was given to examples where although the resin had flowed out by not more than 2 mm, the resin did not reach the end surface of the copper foil in the first place.

### Embedding Property

There was prepared a substrate for evaluation that had a size of 95 mm×95 mm×0.44 mm (a laminated body of a 0.4 mm thick glass epoxy substrate and two pieces of 18 μm thick copper foil), and then with respect to a 50 mm-squared area in the center of the substrate, only the copper foil was subjected to etching to obtain a substrate for evaluation that had a circuit of L/S=75/75 μm.

An uncured film having a size of 100 mm×100 mm×50 μm was stacked on the circuit-formed surface of such substrate for evaluation, and a tetrafluoroethylene-ethylene copolymer resin film (AFLEX by AGC Inc.) was further stacked thereon, followed by performing molding at 180° C. and 3 MPa for two hours. The cross-section of such laminated body was observed using a microscope. Here, ◯ was given to examples where no voids were confirmed at all, Δ was given to examples where 1 to 3 voids were confirmed, □ was given to examples where 4 or more voids were confirmed, and x was given to examples exhibiting an unfilled condition. FIG. 5 shows a cut end surface of a molded substrate whose tetrafluoroethylene-ethylene copolymer resin film has been removed.

TABLE 3

| Composition compounding table | | | Working example | | | | |
|---|---|---|---|---|---|---|---|
| (part by mass) | | | 9 | 10 | 11 | 12 | 13 |
| (A-1) | BMI-2500 | A-1-1 | 75.0 | 75.0 | 75.0 | 75.0 | 75.0 |
| (A-2) | BMI-1500 | A-2-3 | 25.0 | | 25.0 | 20.0 | 25.0 |
| | BMI-5000 | A-2-4 | | 25.0 | | | |
| (A-3) | BMI-1000 | A-3-2 | | | | 5.0 | |
| | MIR-3000 | A-3-3 | | | | | |
| (B) | Trigonox B | B1-1 | 1.0 | 1.0 | | 1.0 | 1.0 |
| | Perkadox 14S-FL | B1-2 | | | 1.0 | | |
| | Laurox | B-2 | | | | | |
| (C) | BHT SWANOX | C-1 | 0.01 | 0.01 | 0.01 | 0.01 | 0.01 |
| (Inorganic | SO-25R | | 100.0 | 100.0 | 100.0 | 100.0 | |
| filler) | | | | | | | |
| (Solvent) | Cyclohexanone | | 100.0 | 100.0 | 100.0 | 100.0 | 100.0 |
| Evaluation | Relative permittivity at 10 GHz | | 2.92 | 2.94 | 2.96 | 3.01 | 2.52 |
| results | Relative permittivity at 40 GHz | | 2.95 | 2.93 | 3.01 | 3.07 | 2.55 |
| | Dielectric tangent at 10 GHz | | 0.0012 | 0.0011 | 0.0012 | 0.0020 | 0.0019 |
| | Dielectric tangent at 40 GHz | | 0.0012 | 0.0011 | 0.0012 | 0.0024 | 0.0022 |
| | Ratio of change in dielectric | % | 0 | 0 | 0 | 20 | 16 |
| | tangent | | | | | | |
| | Peeling strength | kN/m | 0.9 | 0.8 | 0.9 | 0.7 | 1.2 |
| | Moldability (flow property) | | ◯ | ◯ | ◯ | ◯ | Δ |
| | Embedding property | | ◯ | Δ | ◯ | ◯ | ◯ |

TABLE 4

| Composition compounding table | | | Comparative example | | | | |
|---|---|---|---|---|---|---|---|
| (part by mass) | | | 13 | 14 | 15 | 16 | 17 |
| (A-1) | BMI-2500 | A-1-1 | | | 75.0 | 75.0 | 75.0 |
| (A-2) | BMI-1500 | A-2-3 | | | | | |
| | BMI-5000 | A-2-4 | 100.0 | 100.0 | | | |
| (A-3) | BMI-1000 | A-3-2 | | | 25.0 | | |
| | MIR-3000 | A-3-3 | | | | 25.0 | 25.0 |
| (B) | Trigonox B | B1-1 | 1.0 | | 1.0 | 1.0 | 1.0 |
| | Perkadox 14S-FL | B1-2 | | | | | |
| | Laurox | B-2 | | 1.0 | | | |
| (C) | BHT SWANOX | C-1 | 0.01 | 0.01 | 0.01 | 0.01 | 0.01 |
| (Inorganic | SO-25R | | 100.0 | 100.0 | 100.0 | 100.0 | |
| filler) | | | | | | | |
| (Solvent) | Cyclohexanone | | 100.0 | 100.0 | 100.0 | 100.0 | 100.0 |
| Evaluation | Relative permittivity at 10 GHz | | 2.88 | 3.09 | 3.14 | 3.17 | 2.78 |
| results | Relative permittivity at 40 GHz | | 2.88 | 3.12 | 3.32 | 3.21 | 2.91 |
| | Dielectric tangent at 10 GHz | | 0.0012 | 0.0021 | 0.0031 | 0.0025 | 0.0034 |
| | Dielectric tangent at 40 GHz | | 0.0012 | 0.0029 | 0.0045 | 0.0032 | 0.0051 |
| | Ratio of change in dielectric | % | 0 | 38 | 45 | 28 | 50 |
| | tangent | | | | | | |
| | Peeling strength | kN/m | 1.5 | <0.1 | 0.5 | 0.4 | 0.8 |
| | Moldability (flow property) | | □ * | X | X | ◯ | □ |
| | Embedding property | | ◯ | X | □ | ◯ | ◯ |
| Composition compounding table | | | Comparative example | | | | |
| (part by mass) | | | 18 | 19 | 20 | 21 ** | 22 ** |
| (A-1) | BMI-2500 | A-1-1 | 75.0 | 100.0 | 100.0 | | |
| (A-2) | BMI-1500 | A-2-3 | | | | 100.0 | 100.0 |
| | BMI-5000 | A-2-4 | | | | | |
| (A-3) | BMI-1000 | A-3-2 | | | | | |
| | MIR-3000 | A-3-3 | 25.0 | | | | |
| (B) | Trigonox B | B1-1 | | 1.0 | 1.0 | 1.0 | 1.0 |
| | Perkadox 14S-FL | B1-2 | | | | | |
| | Laurox | B-2 | 1.0 | | | | |
| (C) | BHT SWANOX | C-1 | 0.01 | 0.01 | 0.01 | 0.01 | 0.01 |
| (Inorganic | SO-25R | | | 100.0 | | 100.0 | |
| filler) | | | | | | | |
| (Solvent) | Cyclohexanone | | 100.0 | 100.0 | 100.0 | 100.0 | 100.0 |
| Evaluation | Relative permittivity at 10 GHz | | 2.91 | 2.91 | 2.52 | 2.91 | 2.49 |
| results | Relative permittivity at 40 GHz | | 3.14 | 3.05 | 2.65 | 2.91 | 2.50 |
| | Dielectric tangent at 10 GHz | | 0.0052 | 0.0012 | 0.0021 | 0.0017 | 0.0023 |
| | Dielectric tangent at 40 GHz | | 0.0089 | 0.0013 | 0.0029 | 0.0017 | 0.0023 |
| | Ratio of change in dielectric | % | 71 | 8 | 38 | 0 | 0 |
| | tangent | | | | | | |
| | Peeling strength | kN/m | <0.1 | 0.5 | 0.6 | Not | Not |
| | Moldability (flow property) | | X | X | X | conducted | conducted |
| | Embedding property | | □ | X | X | | |

* Although the pressure was lowered to 0.5 MPa, flow out was unable to be remedied.
** Surface tackiness was so severe that an uncured film was unable to be obtained; only relative permittivity and dielectric tangent were measured.

What is claimed is:

1. A heat-curable maleimide resin composition comprising:
(A) two or more kinds of maleimide compound having at least one dimer acid frame-derived hydrocarbon group per molecule; and
(B) a reaction initiator,
wherein a cured product of the heat-curable maleimide resin composition has a dielectric tangent of not larger than 0.003 both at 10 GHz and 40 GHz.

2. The heat-curable maleimide resin composition according to claim 1, wherein at least one kind of the component (A) is a maleimide compound (A-1) represented by a formula (1), and at least one other kind of the component (A) is a maleimide compound (A-2) represented by a formula (3), the formula (1) being expressed as 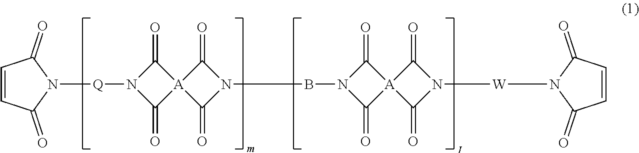
wherein A independently represents a tetravalent organic group having a cyclic structure, B independently represents a divalent hydrocarbon group having 6 to 200 carbon atoms, Q independently represents a divalent alicyclic hydrocarbon group having 6 to 60 carbon atoms, W is B or Q, at least one of B and W is a dimer acid frame-derived hydrocarbon group, l is 1 to 100, m is 1 to 200, no restrictions are imposed on an order of each repeating unit identified by m and l, and a bonding pattern may be alternate, block or random; the formula (3) being expressed as 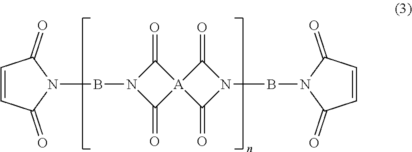
wherein A independently represents a tetravalent organic group having a cyclic structure, B independently represents a divalent hydrocarbon group having 6 to 200 carbon atoms, at least one B represents a dimer acid frame-derived hydrocarbon group, and n is 0 to 100.

3. The heat-curable maleimide resin composition according to claim 2, wherein A in the formulae (1) and (3) is any one of the tetravalent organic groups represented by the following structural formulae

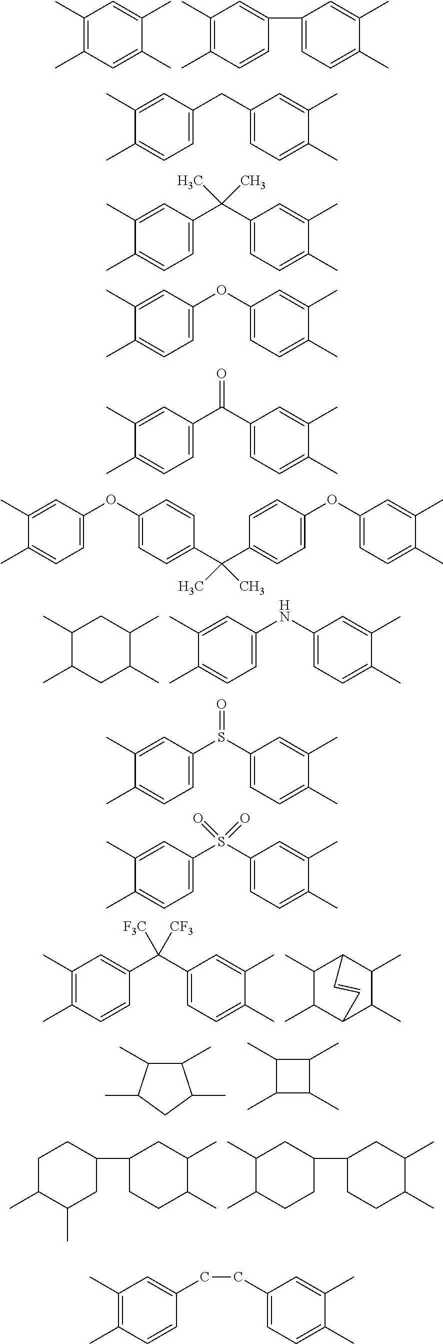

4. The heat-curable maleimide resin composition according to claim 1, wherein a ratio of change of the dielectric tangent of the cured product at 40 GHz to the dielectric tangent thereof at 10 GHz is not higher than +/−30%.

5. The heat-curable maleimide resin composition according to claim 1, wherein the reaction initiator as the component (B) is (B1) an organic peroxide having a one-hour half-life temperature of not lower than 140° C.

6. The heat-curable maleimide resin composition according to claim 5, further comprising a polymerization inhibitor as a component (C).

7. An uncured film for substrate formation comprising the heat-curable maleimide resin composition according to claim 1.

8. A cured film for substrate formation comprising the cured product of the heat-curable maleimide resin composition according to claim 1.

9. A prepreg comprising the heat-curable maleimide resin composition according to claim 1 and a fiber base material.

10. A laminate comprising the cured product of the heat-curable maleimide resin composition according to claim 1.

11. A printed-wiring board comprising the cured product of the heat-curable maleimide resin composition according to claim 1.
